(19) United States
(12) Patent Application Publication
(10) Pub. No.: US 2023/0160063 A1
(43) Pub. Date: May 25, 2023

(54) EXHAUST PIPE APPARATUS

(71) Applicant: Kioxia Corporation, Tokyo (JP)

(72) Inventors: Akihiro Oishi, Yokohama Kanagawa (JP); Hiroshi Matsuba, Fujisawa Kanagawa (JP); Hiroyuki Fukumizu, Yokohama Kanagawa (JP)

(73) Assignee: Kioxia Corporation, Tokyo (JP)

(21) Appl. No.: 17/853,569

(22) Filed: Jun. 29, 2022

(30) Foreign Application Priority Data
Nov. 25, 2021 (JP) 2021-191125

(51) Int. Cl. C23C 16/44; H05H 1/46

(52) U.S. Cl. CPC C23C 16/4412; C23C 16/4408; H05H 1/466; H05H 2242/10; H05H 2245/40

(57) ABSTRACT

An exhaust pipe apparatus according to an embodiment includes a dielectric pipe; a radio-frequency electrode; and a plasma generation circuit. The exhaust pipe apparatus functions as a part of an exhaust pipe disposed between a process chamber and a vacuum pump that exhausts gas inside the process chamber. The radio-frequency electrode includes a thin metal plate disposed on an outer periphery side of the dielectric pipe, a buffer member disposed on an outer periphery side of the thin metal plate, and a conductive hollow structure disposed on an outer periphery side of the buffer member and a radio-frequency voltage is applied to the radio-frequency electrode. The plasma generation circuit generates plasma inside the dielectric pipe.

### CROSS-REFERENCE TO RELATED APPLICATION

This application is based upon and claims the benefit of priority from Japanese Patent Application No. 2021-191125 filed on Nov. 25, 2021 in Japan, the entire contents of which are incorporated herein by reference.

### FIELD

Embodiments described herein relate generally to an exhaust pipe apparatus.

### BACKGROUND

In a film forming apparatus represented by a chemical vapor deposition (CVD) apparatus, a source gas is introduced into a film forming chamber to form a desired film on a substrate disposed in the film forming chamber. The source gas remaining in the film forming chamber is exhausted by a vacuum pump through an exhaust pipe. There have been undesirable situations at that time such as closure of the exhaust pipe by deposition of products in the exhaust pipe due to the source gas, and stop of the vacuum pump downstream of the exhaust pipe by deposition of the products in the vacuum pump. In order to remove the deposit, a cleaning process by a remote plasma source (RPS) apparatus is performed. However, since an RPS apparatus generally focuses on cleaning in the film forming chamber, cleaning performance has been insufficient to clean products deposited in the exhaust pipe near the vacuum pump and the vacuum pump that is distant from the RPS apparatus.

In addition, a technique is disclosed in which a radio-frequency voltage is applied to a radio-frequency electrode disposed on the outer periphery of a conduit of an insulating material such as ceramics or quartz to generate plasma inside the conduit. Here, unreacted gas and waste gas generated in the steps of asking, etching, vapor deposition, cleaning, and nitriding is removed by the plasma. However, when the contact between the conduit and the radio-frequency electrode is insufficient, a problem that plasma generation inside the conduit becomes uneven may occur.

### BRIEF DESCRIPTION OF THE DRAWINGS

FIG. 1 is a configuration diagram illustrating an example of a configuration of an exhaust system of a semiconductor manufacturing apparatus according to a first embodiment;

FIG. 2 is a cross-sectional view of an example of an exhaust pipe apparatus according to the first embodiment as viewed from the front side;

FIG. 3 is a cross-sectional view of an example of the exhaust pipe apparatus according to the first embodiment as viewed from the upper side;

FIG. 4 is a diagram illustrating an example of a configuration of a radio-frequency electrode according to the first embodiment;

FIG. 5 is a diagram illustrating an example of how to assemble the radio-frequency electrode in the first embodiment;

FIG. 6 is a top view illustrating an example of a plasma generation state in Comparative Example 1 of the first embodiment;

FIG. 7 is a top view illustrating an example of a plasma generation state in the first embodiment;

FIG. 8 is a graph for explaining the relationship between the inner pipe temperature and the cleaning processing time;

FIG. 9 is a diagram illustrating an example of a layout of cooling pipes according to the first embodiment;

FIG. 10 is a front view of an example of an exhaust pipe apparatus according to Comparative Example 2 of the first embodiment;

FIG. 11 is a cross-sectional view of an example of an exhaust pipe apparatus according to a second embodiment as viewed from the front side; and

FIG. 12 is a cross-sectional view of an example of an exhaust pipe apparatus according to a third embodiment as viewed from the front side.

### DETAILED DESCRIPTION

An exhaust pipe apparatus according to an embodiment includes a dielectric pipe; a radio-frequency electrode; and a plasma generation circuit. The exhaust pipe apparatus functions as a part of an exhaust pipe disposed between a process chamber and a vacuum pump that exhausts gas inside the process chamber. The radio-frequency electrode includes a thin metal plate disposed on an outer periphery side of the dielectric pipe, a buffer member disposed on an outer periphery side of the thin metal plate, and a conductive hollow structure disposed on an outer periphery side of the buffer member and a radio-frequency voltage is applied to the radio-frequency electrode. The plasma generation circuit generates plasma inside the dielectric pipe.

In addition, hereinafter, the embodiment provides an exhaust pipe apparatus capable of bringing plasma generation close to a uniform state and removing products deposited inside the exhaust pipe near the vacuum pump.

### First Embodiment

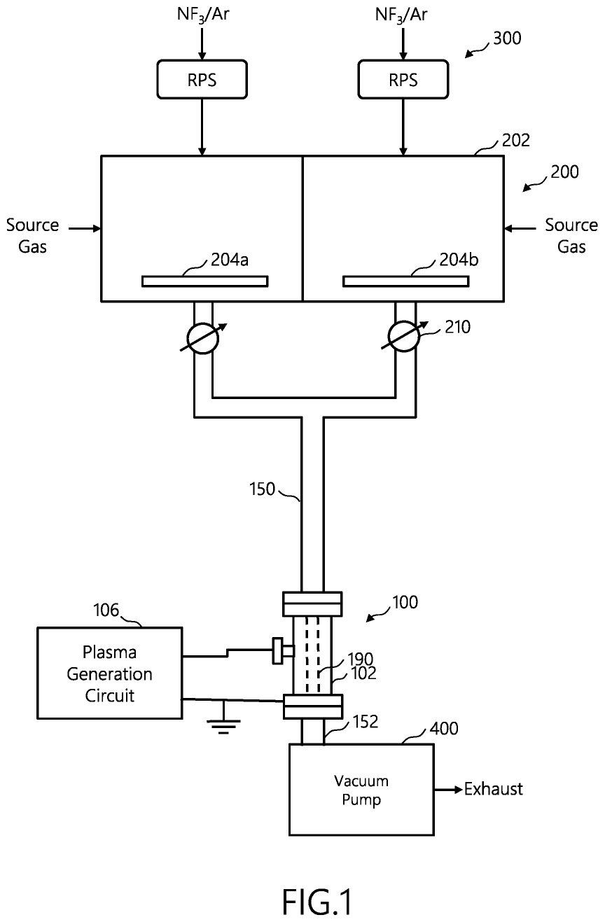

FIG. 1 is a configuration diagram illustrating an example of a configuration of an exhaust system of a semiconductor manufacturing apparatus according to a first embodiment. In the example of FIG. 1, a film forming apparatus, for example, a chemical vapor deposition (CVD) apparatus 200 is illustrated as a semiconductor manufacturing apparatus. In the example of FIG. 1, the CVD apparatus 200 of a multi-chamber type in which two film forming chambers 202 are disposed is illustrated. In the CVD apparatus 200, semiconductor substrates 204 (204a, 204b) on which a film is formed are disposed in the film forming chambers 202 controlled to a desired temperature. Then, vacuuming is performed through exhaust pipes 150 and 152 by a vacuum pump 400, and the source gas is supplied into the film forming chambers 202 controlled to a desired pressure by a pressure adjusting valve 210. In the film forming chambers 202, desired films are formed on the substrates 204 by chemical reaction of the source gas. For example, a silane (SiH₄)-based gas is introduced as a main source gas to form a silicon oxide film (SiO film) or a silicon nitride film (SiN film). Alternatively, for example, tetraethoxysilane (TEOS) gas or the like is introduced as a main source gas to form a silicon oxide film (SiO film). When these films are formed, products due to such a source gas are deposited in the film forming chambers 202 and the exhaust pipes 150 and 152. Therefore, in the film forming process cycle, a cleaning step is performed in addition to the film forming step.

In the cleaning step, a cleaning gas or a purge gas is supplied to a remote plasma source (RPS) apparatus 300 disposed on the upstream side of the film forming chamber 202, and fluorine (F) radicals are generated by plasma. Examples of the cleaning gas include nitrogen trifluoride (NF₃) gas. Examples of the purge gas include argon (Ar) gas. Then, by supplying (diffusing) F radicals into the film forming chambers 202 and toward the exhaust pipe 150, products that are deposited are cleaned. After decomposition of the deposit by cleaning, for example, silicon tetrafluoride (SiF₄) is generated. Since silicon tetrafluoride (SiF₄) has high volatility, silicon tetrafluoride is exhausted from the vacuum pump 400 through the exhaust pipes 150 and 152.

However, the F radicals hardly reach portions of the exhaust pipes 150, 152 away from the film forming chamber 202. Therefore, cleaning performance is deteriorated. In particular, at positions close to the inlet port of the vacuum pump 400, the cleaning rate is lower because the pressure is lower. As a result, the inside of the exhaust pipes 150 and 152 may be blocked by the deposited products. In addition, the gap between the rotor and the casing may be filled with the products deposited in the vacuum pump 400, which causes an overload state and then the vacuum pump 400 may be stopped. Therefore, in the first embodiment, an exhaust pipe apparatus 100 is disposed at a position closer to the inlet port of the vacuum pump 400 than to the film forming chambers 202 as illustrated in FIG. 1.

In FIG. 1, the exhaust pipe apparatus 100 in the first embodiment is used as a part of an exhaust pipe including the exhaust pipes 150 and 152 disposed between the film forming chamber 202 (an example of a process chamber) and the vacuum pump 400 that exhausts the inside of the film forming chamber 202. The exhaust pipe apparatus 100 includes an outer pipe 102, an inner pipe 190 (dielectric pipe) made of a dielectric, and a plasma generation circuit 106. For the outer pipe 102, for example, a pipe material of the same material as that of the normal exhaust pipes 150 and 152 is used. For example, a stainless steel material such as SUS 304 is used. However, as a material of the outer pipe 102, SUS 316 steel material is more preferably used from the viewpoint of corrosion resistance against the cleaning gas. In addition, for the outer pipe 102, for example, a pipe material having the same size as that of the normal exhaust pipes 150 and 152 is used. However, the material and size are not limited to those described above. A pipe having a size larger than that of the exhaust pipes 150 and 152 may be used. Alternatively, a pipe having a smaller size may be used.

Flanges are disposed at both end portions of the inner pipe 190 and the outer pipe 102, one end portions thereof are connected to the exhaust pipe 150 having a flange of the same size, and the other end portions thereof are connected to the exhaust pipe 152 having a flange of the same size. In FIG. 1, a clamp and the like for fixing the flanges of the exhaust pipe apparatus 100 and the flanges of the exhaust pipes 150 and 152 are not illustrated. Hereinafter, the same applies to each drawing. In addition, a seal material such as an O-ring used for connection with the exhaust pipes 150 and 152 is not illustrated. Hereinafter, in each embodiment, the exhaust pipe 152 is sandwiched between the exhaust pipe apparatus 100 and the vacuum pump 400, but it is not limited to this configuration. The exhaust pipe apparatus 100 may be disposed directly at the inlet port of the vacuum pump 400. The inner pipe 190 made of a dielectric is disposed inside the outer pipe 102. The plasma generation circuit 106 generates capacitively coupled plasma (CCP) inside the inner pipe 190 made of a dielectric using an electrode, which will be described later, disposed on the outer periphery side of the inner pipe 190.

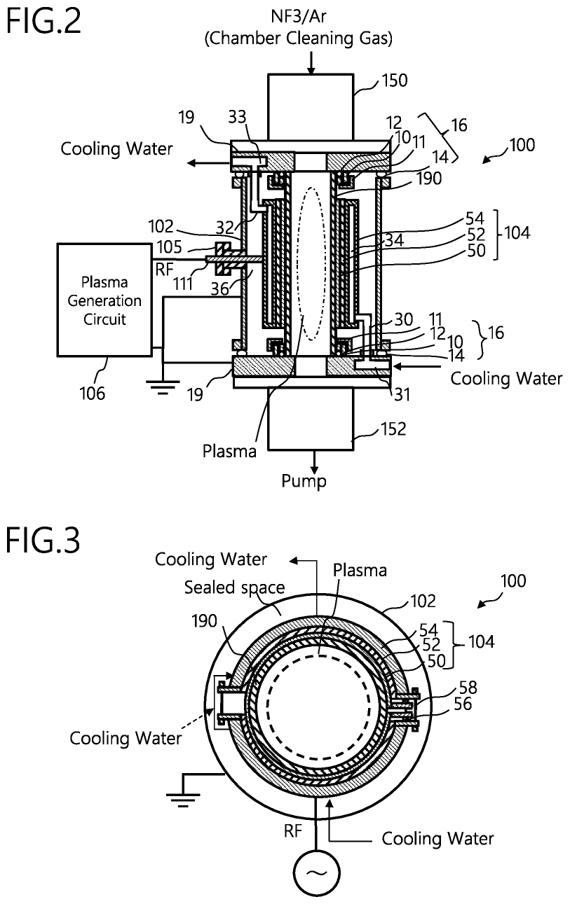

FIG. 2 is a cross-sectional view of an example of the exhaust pipe apparatus according to the first embodiment as viewed from the front side. FIG. 3 is a cross-sectional view of an example of the exhaust pipe apparatus according to the first embodiment as viewed from the upper side. In FIG. 2, the cross-sectional structure is of the exhaust pipe apparatus 100, and cross-sectional structures of other components are not illustrated. Hereinafter, the same applies to each cross-sectional view as viewed from the front side. In FIGS. 2 and 3, the exhaust pipe apparatus 100 is formed in a double pipe structure of the outer pipe 102 and the inner pipe 190 made of a dielectric and disposed inside the outer pipe 102. The inner pipe 190 is formed to have a shape similar to that of the outer pipe 102. In the example of FIGS. 2 and 3, corresponding to the cylindrical outer pipe 102 having a circular cross section (annular), the cylindrical inner pipe 190 having a circular cross section (annular) similar to that of the outer pipe 102 is used. Alternatively, corresponding to a cylindrical outer pipe 102 having a rectangular cross section, a cylindrical inner pipe 190 having a rectangular cross section similar to that of the outer pipe 102 may be used.

The inner pipe 190 is disposed to be separated from the inner wall of the outer pipe 102 by a space 36. The material of the dielectric to be the inner pipe 190 may be any material having a dielectric constant larger than that of air. As a material of the inner pipe 190, for example, quartz, alumina (Al₂O₃), yttria (Y₂O₃), hafnia (HfO₂), zirconia (ZrO₂), magnesium oxide (MgO), aluminum nitride (AlN), or the like is preferably used. The thickness of the inner pipe 190 may be appropriately set as long as the exhaust performance is not hindered.

A radio-frequency electrode 104 is disposed inner than the outer pipe 102 and on the outer periphery side of the inner pipe 190. The radio-frequency electrode 104 includes a thin metal plate 50 disposed on the outer periphery side of the inner pipe 190 serving as a dielectric pipe, a buffer member 52 disposed on the outer periphery side of the thin metal plate 50, and a conductive hollow structure 54 disposed on the outer periphery side of the buffer member 52. The thin metal plate 50 and the hollow structure 54 are disposed so as to be electrically conductive.

In a state where the radio-frequency electrode 104 is disposed on the outer periphery side of the inner pipe 190, the radio-frequency electrode 104 is formed in a shape corresponding to the outer peripheral shape of the inner pipe 190. For example, the cylindrical (annular) radio-frequency electrode 104 having the same type of circular cross-section is used for the cylindrical (annular) inner pipe 190 having a circular cross-section. As illustrated in FIG. 2, the length of the radio-frequency electrode 104 is shorter than the length of the inner pipe 190. As illustrated in the example of FIG. 2, the radio-frequency electrode 104 is disposed at the center in the height direction with a gap left between the upper end side and the lower end side of the inner pipe 190.

Flanges 19 are disposed on the end portion side of the inner pipe 190. In the example of FIG. 2, the flanges 19 for piping are disposed at both end portions of the inner pipe 190. The flange 19 disposed upstream with respect to the flow of the gas and the flange of the exhaust pipe 150 are fixed to each other. The flange 19 disposed downstream with respect to the flow of the gas and the flange of the exhaust pipe 152 are fixed to each other. For both of the flanges 19, for example, a pipe material of the same material as that of the normal exhaust pipes 150 and 152 is used. For example, a stainless steel material such as SUS 304 is used. However, as a material of the flanges 19, SUS 316 steel material is more preferably used from the viewpoint of corrosion resistance against the cleaning gas.

In the first embodiment, as illustrated in FIG. 2, the space between the outer pipe 102 and the inner pipe 190 is blocked from the ambient atmosphere and the space in the inner pipe 190 by seal mechanisms 16 disposed at the upper and lower end portions of the inner pipe 190 and the outer pipe 102 covering the outer periphery side of the inner pipe 190. The seal mechanisms 16 are preferably configured as follows, for example. Each of the seal mechanisms 16 includes a protrusion 10, an O-ring retainer 11, an O-ring 12, and an O-ring 14. Protrusions 10 are provided in a ring shape on the surfaces of the respective flanges 19 at both end portions of the inner pipe 190, and extend from the surfaces of the respective flanges 19 toward the radio-frequency electrode 104, on the outer side of the inner pipe 190. The (upstream) O-ring 14 closer to the exhaust pipe 150 is disposed between the (upstream) flange surface of the outer pipe 102 closer to the exhaust pipe 150 and the flange 19. The (downstream) O-ring 14 closer to the exhaust pipe 152 is disposed between the (downstream) flange surface of the outer pipe 102 closer to the exhaust pipe 152 and the flange 19. In such a case, on the upstream side of the exhaust pipe apparatus 100, the flange of the outer pipe 102 and the flange of the pipe 150 are preferably clamp-connected with the flange 19 interposed therebetween. On the downstream side of the exhaust pipe apparatus 100, the flange of the outer pipe 102 and the flange of the pipe 152 are preferably clamp-connected with the flange 19 interposed therebetween. The O-ring 14 shields the atmosphere inside the outer pipe 102 from the ambient atmosphere.

Each O-ring 12 is disposed in a state of being pressed between the outer peripheral surface of the end portion of the inner pipe 190 and the inner peripheral surface of the protrusion 10. Therefore, the protrusion 10 is formed to have the inner diameter larger than the outer diameter size of the inner pipe 190 and have the outer diameter smaller than the inner diameter size of the outer pipe 102. Each O-ring 12 is pressed by the O-ring retainer 11. The O-ring retainer 11 may be formed as one member, or may be formed as a combination of two members, that is, a ring-shaped member disposed between the outer peripheral surface of the end portion of the inner pipe 190 and the inner peripheral surface of the protrusion 10, and an outer member supporting the ring-shaped member as illustrated in FIG. 2. As a result, the atmosphere in the inner pipe 190 is shielded from the space 36 between the outer pipe 102 and the inner pipe 190 via the O-ring 12.

In the first embodiment, by forming the sealed double pipe structure of the outer pipe 102 and the inner pipe 190 as described above, it is possible to prevent the gas flowing through the exhaust pipe from leaking to the ambient atmosphere even when the inner pipe 190 made of the dielectric is damaged. Similarly, it is possible to prevent atmospheric air from intruding into (inflow to) the exhaust pipe. Even when the space between the outer pipe 102 and the inner pipe 190 is controlled to the atmospheric pressure, it is possible to prevent inflow of the atmospheric air to such an extent that a failure of the vacuum pump 400 occurs because the volume of the space between the outer pipe 102 and the inner pipe 190 is small.

In the examples of FIGS. 2 and 3, the double pipe structure in which the outer pipe 102 is disposed outside the inner pipe 190 is illustrated, but it is not limited thereto. The absence of the outer pipe 102 is not excluded.

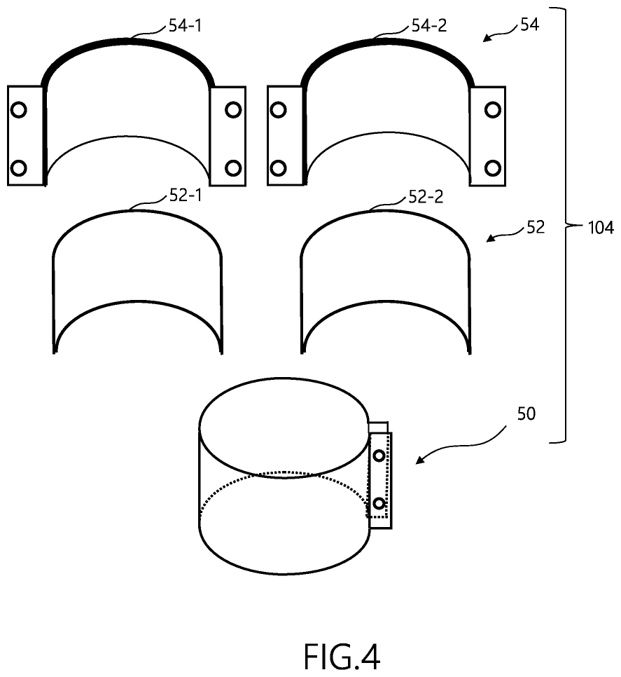

FIG. 4 is a diagram illustrating an example of a configuration of a radio-frequency electrode according to the first embodiment. As described above, the radio-frequency electrode 104 includes the thin metal plate 50, the buffer member 52, and the hollow structure 54.

The thin metal plate 50 is thinner than the hollow structure 54. Thus, the thin metal plate can be bent easier than the hollow structure 54. Specifically, the thin metal plate 50 is formed by bending a thin metal plate into an annular shape, for example, a circular shape. For example, a thin plate having a thickness of about 0.1 mm to 3 mm is used. Flanges folded outward are formed at both ends in a direction in which the thin plate is bent. A bolt hole is formed in the flange. In the example of FIG. 4, two upper and lower bolt holes are formed. As the material of the thin metal plate 50, a soft material having a low resistivity is suitable. For example, it is preferable to use copper (Cu) or aluminum (Al). Since the resistivity is low, even when the thickness is small, the entire surface can be easily electrically at the same potential as the hollow structure 54. In addition, it can be easily bent by being soft. By using, for example, a copper material that is softer than the stainless material, it can be easily bent even when the thickness is, for example, 3 mm.

The hollow structure 54 is formed as a combination of one half hollow structure 54-1 and the other half hollow structure 54-2 obtained by halving a circumference of a cylindrical shape. A cavity 34 is formed in the hollow structure 54. Specifically, the cavity 34 is formed in each of the half hollow structure 54-1 and the half hollow structure 54-2. The cavity 34 is suitably formed throughout the hollow structure 54. The hollow structure 54 is formed of a conductive material. In addition, as will be described later, a copper material having high conductivity, for example, is used from the viewpoint of flowing cooling water into the cavity 34. Alternatively, an aluminum material or a steel material such as SUS 304 or SUS 316 may be used. The hollow structure 54 guides the radio-frequency potential applied from the introduction terminal 111 to the thin metal plate 50 and functions as a heat exchanger that is a part of the cooling mechanism. A flange for attachment is formed at half ends of the half hollow structure 54-1 and the half hollow structure 54-2. A bolt hole is formed in the flange. In the example of FIG. 4, two upper and lower bolt holes are formed. The bolt holes of the half hollow structure 54-1 and the half hollow structure 54-2 are formed so as to be displaced from the bolt holes of the thin metal plate 50.

The buffer member 52 is sandwiched between the thin metal plate 50 and the hollow structure 54 and functions as a buffer material for both. The buffer member 52 is formed as a combination of one half buffer member 52-1 and the other half buffer member 52-2 obtained by halving a circumference of a cylindrical shape. The buffer member 52 is desirably made of a material having high thermal conductivity in order to efficiently transfer heat from the inner pipe 190 serving as the dielectric pipe to the hollow structure 54. The thermal conductivity is preferably, for example, about 1 to 10 W/mK. In addition, heat resistance that can withstand heat generated in the dielectric is desired. For example, heat resistance of about 100 to 150° C. is preferable. As a material having these functions, for example, a sheet-like silicone polymer is preferably used as the buffer member 52. Alternatively, as the buffer member 52, a silicone gel material may be suitably applied to the inner surface of the hollow structure 54. The thickness of the buffer member 52 is preferably about 0.1 to 0.5 mm, for example.

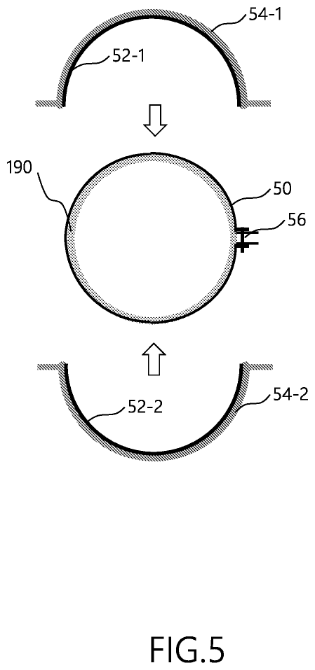

FIG. 5 is a diagram illustrating an example of how to assemble the radio-frequency electrode in the first embodiment. First, the thin metal plate 50 is attached to the outer periphery of the inner pipe 190. The thin metal plate 50 can bring the thin metal plate 50 into close contact with the outer peripheral surface of the inner pipe 190 by inserting screws 56 into the bolt holes of the flanges and fastening the flanges so as to approach each other.

Next, the thin metal plate 50 is attached from the outer periphery side so as to be sandwiched between the half hollow structure 54-1 in which the half buffer member 52-1 is disposed on the inner surface and the half hollow structure 54-2 in which the half buffer member 52-2 is disposed on the inner surface. Then, the hollow structure 54 is attached to the outer periphery side of the thin metal plate 50 via the buffer member 52 by inserting screws 58 into the bolt holes of the flanges between the half hollow structure 54-1 and the half hollow structure 54-2 and fastening the flanges so as to approach each other. At that time, as illustrated in FIG. 3, the assembly is performed such that the tips of the screws 56 in contact with the thin metal plate 50 are in contact with the hollow structure 54. As a result, the hollow structure 54 can be electrically connected to the thin metal plate 50. Note that the half hollow structure 54-1 and the half hollow structure 54-2 are electrically connected to each other via the screws 58.

Although the case where the hollow structure 54 is electrically connected to the thin metal plate 50 using the screws 56 has been described, it is not limited thereto. For example, conductive nanoparticles may be added to the silicone polymer serving as the buffer member 52. As a result, the buffer member 52 may be configured to electrically connect the hollow structure 54 and the thin metal plate 50.

In the example of FIGS. 2 and 3, a radio-frequency (RF) electric field is applied to the radio-frequency electrode 104 by the plasma generation circuit 106. Specifically, an introduction terminal 111 (an example of a radio-frequency introduction terminal) is introduced into the outer pipe 102 from an introduction terminal port 105 connected to the outer peripheral surface of the outer pipe 102, and the introduction terminal 111 is connected to the radio-frequency electrode 104. In the first embodiment, the flanges 19 function as ground electrodes. The outer pipe 102 is also grounded.

Then, the plasma generation circuit 106 generates plasma inside the inner pipe 190 using capacitive coupling between the radio-frequency electrode 104 and the ground electrodes. Specifically, in a state where the flange 19 is grounded (ground potential is applied) as a ground electrode, the plasma generation circuit 106 applies a radio-frequency (RF) voltage to the hollow structure 54 of the radio-frequency electrode 104 via the introduction terminal 111. As a result, the thin metal plate 50 electrically connected to the hollow structure 54 has the same potential as the hollow structure 54. Therefore, capacitively coupled plasma (CCP) is generated in the inner pipe 190 of the dielectric by a potential difference between the radio-frequency electrode 104 (thin metal plate 50) and the flange 19. In addition, since in the cleaning step, the cleaning gas such as the NF₃ gas described above is supplied at an upstream position, F radicals due to plasma are generated inside the inner pipe 190 by using the remaining cleaning gas. Then, the F radicals remove products deposited inside the inner pipe 190. Thus, high cleaning performance can be exhibited in the exhaust pipe.

Thereafter, for example, SiF₄ generated after decomposition of the deposit by F radicals has high volatility, and thus is exhausted by the vacuum pump 400 through the exhaust pipe 152. In addition, a part of the radicals generated in the exhaust pipe apparatus 100 enters the vacuum pump 400 through the exhaust pipe 152, and cleans the products deposited in the vacuum pump 400. As a result, the amount of products deposited in the vacuum pump 400 can be reduced. For example, the F radicals generated by the plasma at a part of the inner wall surface on the lower end portion side of the inner pipe 190 can be caused to enter the vacuum pump 400 in a state where the consumption inside the inner pipe 190 is small.

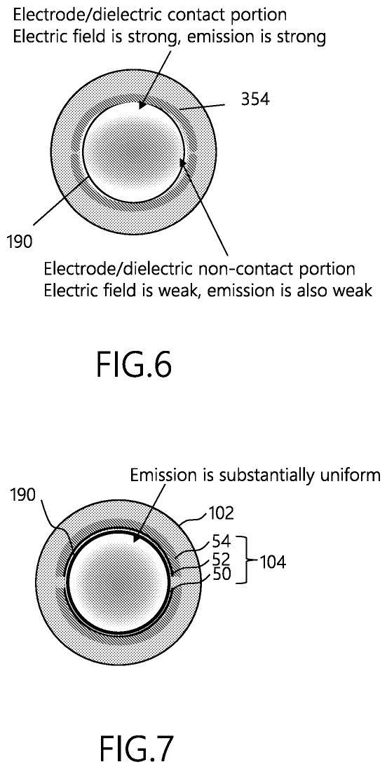

FIG. 6 is a top view illustrating an example of a plasma generation state in Comparative Example 1 of the first embodiment. In Comparative Example 1 illustrated in FIG. 6, in the examples of FIGS. 2 and 3, the hollow structure 354 is directly disposed on the outer periphery of the inner pipe 190 without disposing the thin metal plate 50 and the buffer member 52. In Comparative Example 1, when the hollow structure 354 is attached around the inner pipe 190, a contact portion and a non-contact portion are generated between the inner peripheral surface of the hollow structure 354 and the outer peripheral surface of the inner pipe 190. In a case where a radio-frequency voltage is applied to the hollow structure 354, the radio-frequency electric field is strong and plasma emission is strong at a contact portion, whereas the radio-frequency electric field is weak and plasma emission is weak at a non-contact portion. As described above, in the configuration of Comparative Example 1, the plasma does not spread to the non-contact portion, and plasma generation becomes non-uniform. As a result, the cleaning effect is deteriorated.

FIG. 7 is a top view illustrating an example of a plasma generation state in the first embodiment. In the first embodiment, since the thin metal plate 50 having a thickness smaller than that of the hollow structure 54 can be brought into close contact with the inner pipe 190, a non-contact portion can be prevented from being generated between the inner peripheral surface of the thin metal plate 50 and the outer peripheral surface of the inner pipe 190. When a radio-frequency voltage is applied to the hollow structure 54, the entire conductive thin metal plate 50 can be electrically set to substantially the same potential as the hollow structure 54. As a result, as illustrated in FIG. 7, it is possible to expect generation of uniform plasma over the circumferential direction without generating a portion where emission is weak.

Here, in the above-described example, the double pipe structure is configured in order to avoid leakage and atmospheric air intrusion due to a damage of the inner pipe 190 by the dielectric. Causes of a damage of the inner pipe 190 made of a dielectric may include an increase of the temperature of the inner pipe 190.

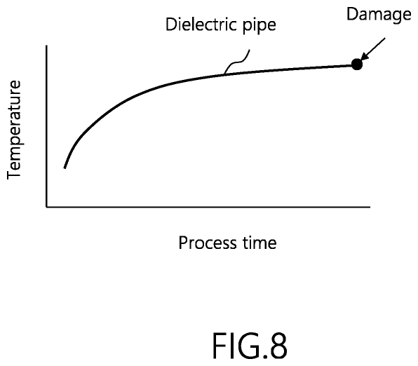

FIG. 8 is a graph for explaining the relationship between the inner pipe temperature and the cleaning processing time. In FIG. 8, the vertical axis represents the temperature of the inner pipe in the exhaust pipe, and the horizontal axis represents the continuous processing time for the exhaust pipe in the cleaning process. In addition, the graph illustrated in the example of FIG. 8 illustrates an example of a case where the inner pipe 190 is used without being cooled. In the cleaning step, the radio-frequency voltage is applied to the radio-frequency electrode 104. Thus, the temperature of the radio-frequency electrode 104 increases. Accordingly, the temperature of the inner pipe 190, which is a dielectric pipe in which plasma is generated, increases. As illustrated in the graph of FIG. 8, if the processing is continued without cooling, the temperature rises as the cleaning processing time increases, and the inner pipe 190 may eventually be damaged. In order to suppress the damage of the inner pipe 190 made of a dielectric due to the temperature increase, it is desirable to cool the inner pipe 190. Therefore, in the first embodiment, a configuration capable of suppressing a temperature rise of the inner pipe 190 will be described below.

In the first embodiment, a cooling mechanism is disposed. The cooling mechanism introduces cooling water (an example of a refrigerant) into the space 34 in the hollow structure 54 to cool the inner pipe 190 (dielectric pipe) via the buffer member 52 and the thin metal plate 50.

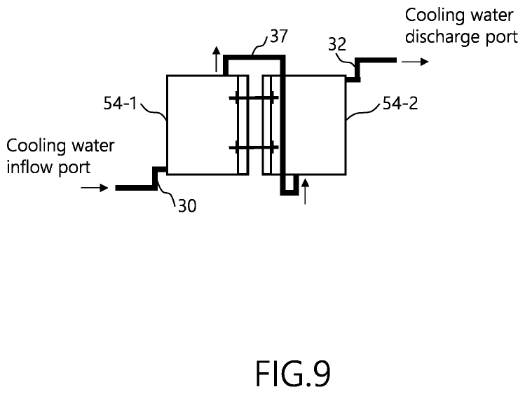

FIG. 9 is a diagram illustrating an example of a layout of cooling pipes according to the first embodiment. As illustrated in the examples of FIGS. 2 and 3, the cavity 34 is formed in the hollow structure 54. The cavity 34 is suitably formed throughout the hollow structure 54. As described above, the hollow structure 54 is formed as a combination of the half hollow structure 54-1 and the half hollow structure 54-2. Therefore, a cooling pipe 30 is disposed below the cavity 34 in the half hollow structure 54-1. A cooling pipe 32 is disposed above the cavity 34 in the half hollow structure 54-2. A cooling pipe 37 is disposed between the upper portion of the cavity 34 in the half hollow structure 54-1 and the lower portion of the cavity 34 in the half hollow structure 54-2. In order to facilitate assembly of the half hollow structure 54-1 and the half hollow structure 54-2, a flexible pipe is preferably used as the cooling pipe 37. However, it is not limited thereto. After the half hollow structure 54-1 and the half hollow structure 54-2 are assembled, a fixed cooling pipe 37 that is difficult to bend freely may be attached.

In the example of FIG. 2, the cavity 31 is formed inside the flange 19 on the exhaust pipe 152 side (downstream side). Similarly, a cavity 33 is formed inside a (upstream) flange 19 closer to the exhaust pipe 150. The cavities 31 and 33 may be formed over the whole or a part of the inside of the respective flanges 19. For example, each cavity may be formed to have an L shape including two cylindrical cavities extending linearly that are connected to each other. The cavity 31 has an inflow port formed in a side surface of the flange 19, and an outflow port formed on the side of the space 36 between the outer pipe 102 and the inner pipe 190. The cavity 33 has an inflow port formed on the side of the space 36 between the outer pipe 102 and the inner pipe 190, and an outflow port formed in a side surface of the flange 19. The cooling pipe 30 connects an outflow port of the cavity 31 and a lower portion of the cavity 34 in the hollow structure 54 (for example, the half hollow structure 54-1). The cooling pipe 37 connects the upper portion of the cavity 34 of the half hollow structure 54-1 and the lower portion of the cavity 34 of the half hollow structure 54-2. In addition, the cooling pipe 32 connects the upper portion of the cavity 34 in the half hollow structure 54-2 and the inflow port of the cavity 33. The flange 19 in which the cavity 31 is formed, the flange 19 in which the cavity 33 is formed, the cooling pipes 30, 32, and 37, and the hollow structure 54 in which the cavity 34 is formed constitute a part of the cooling mechanism.

The cooling water supplied to the side surface of the flange 19 on the exhaust pipe 152 side (downstream side) passes through the cavity 31 in the flange 19 on the exhaust pipe 152 side (downstream side), passes through the cooling pipe 30, and moves to the lower portion of the cavity 34 in the half hollow structure 54-1. The cooling water supplied to the lower portion of the cavity 34 in the half hollow structure 54-1 accumulates in the cavity 34 from the lower portion toward the upper portion. The cooling water overflowing from the upper portion of the cavity 34 in the half hollow structure 54-1 is supplied to the lower portion of the cavity 34 in the half hollow structure 54-2 through the cooling pipe 37. The cooling water supplied to the lower portion of the cavity 34 in the half hollow structure 54-2 accumulates in the cavity 34 from the lower portion toward the upper portion. The cooling water overflowing from the upper portion of the cavity 34 in the half hollow structure 54-2 passes through the cooling pipe 32 and moves to the cavity 33 in the flange 19 on the exhaust pipe 150 side (upstream side). Then, the water passes through the cavity 33 in the flange 19 and is drained from the outflow port in the side surface of the flange 19.

In a state where the cooling water is flowing, the plasma generation circuit 106 generates plasma inside the inner pipe 190 using the radio-frequency electrode 104. The plasma generation circuit 106 applies a radio-frequency voltage to the radio-frequency electrode 104. At this time, the cooling water flowing in the hollow structure 54 is used to cool the inner pipe 190, which is a dielectric pipe whose temperature rises due to plasma generation inside, and the space 36 between the inner pipe 190 and the outer pipe 102. As a result, the radio-frequency voltage is applied, and the radio-frequency electrode 104 whose temperature rises is directly cooled. In the first embodiment, the buffer member 52 having a high thermal conductivity is sandwiched between the hollow structure 54 and the metal thin film 50 so as to be in close contact with each other without any gap. Therefore, the metal thin film 50 can be efficiently cooled by directly cooling the hollow structure 54. Furthermore, the inner pipe 190 in close contact with the inner peripheral surface of the metal thin film 50 can be efficiently cooled. Therefore, the temperature rise of the inner pipe 190 can be suppressed.

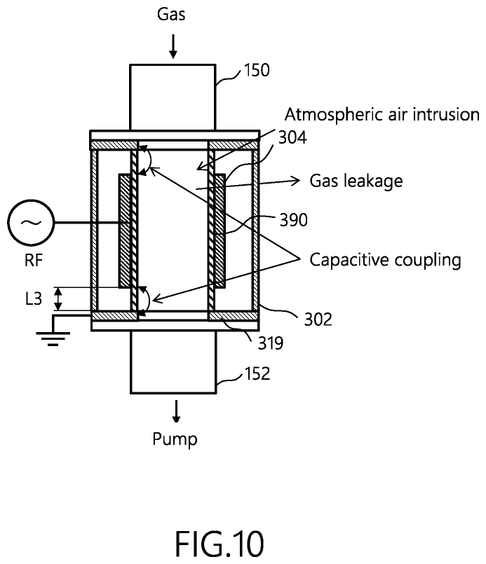

FIG. 10 is a front view of an example of an exhaust pipe apparatus according to Comparative Example 2 of the first embodiment. In Comparative Example 2 of FIG. 10, a case where the radio-frequency electrode 304 is disposed in a space between the outer pipe 302 on the outer periphery side of the dielectric pipe 390 and the dielectric pipe 390 is illustrated. At both end portions of the dielectric pipe 390, pipe flanges 319 that function as ground electrodes are disposed. Then, capacitively coupled plasma (CCP) is generated by applying a radio-frequency (RF) voltage to the radio-frequency electrode 304 using the flanges 319 as ground electrodes. In such a configuration, the flanges 319 and the radio-frequency electrode 304 may be capacitively coupled to cause electric discharge.

In the example of FIG. 10, it is also conceivable to cool the outer peripheral surface of the outer pipe 302 disposed on the outer periphery side of the dielectric pipe 390 and the radio-frequency electrode 304 by supplying cooling water. However, even if the outside of the outer pipe 302 is cooled, it is difficult to sufficiently cool the space between the outer pipe 302 and the dielectric pipe 390 via the outer pipe 302. Therefore, the cooling of the outer pipe 302 may result in increase of the temperature of the dielectric pipe 390 and then damage of the dielectric pipe 390.

On the other hand, in the first embodiment, since the outer peripheral surface of the inner pipe 190 is directly cooled by the radio-frequency electrode 104, the temperature rise of the inner pipe 190 can be suppressed as compared with the case of cooling from the outer side of the outer pipe 102. In the first embodiment, when the double pipe structure in which the outer pipe is disposed outside the inner pipe is not formed, the hollow structure 54 in which the cavity 34 is formed is cooled as a part of the cooling mechanism, so that the temperature rise of the inner pipe 190 can be suitably suppressed.

As described above, according to the first embodiment, plasma generation can be brought close to a uniform state, and a product deposited inside the exhaust pipe near the vacuum pump can be removed.

### Second Embodiment

In the configuration of Comparative Example 2 illustrated in FIG. 10, the flange 319 and the radio-frequency electrode 304 are capacitively coupled to cause electric discharge. The electric discharge may occur not only inside the dielectric pipe 390 but also outside the dielectric pipe 390, for example, on a side where the atmospheric pressure is set. Therefore, it is desirable to increase the distance L3 between the flange 319 (ground electrode) and the radio-frequency electrode 304 to such an extent that the atmospheric pressure side does not cause electric discharge. In a case where the distance L3 between the flange 319 (ground electrode) and the radio-frequency electrode 304 is large, increase of the gas flow rate and the pressure in the dielectric pipe 390 makes it difficult to generate plasma, causing unstable electric discharge. On the other hand, by decreasing the electrode size of the radio-frequency electrode 304 in the gas flow direction to increase the voltage or/and decreasing the distance L3 between the flange 319 (ground electrode) and the radio-frequency electrode 304, plasma is easily generated, but abnormal discharge (arcing) is easily generated on the atmospheric pressure side.

Therefore, in the second embodiment, the ground electrode is disposed such that the distance to the radio-frequency electrode 104 is smaller on the inner side of the inner pipe 190 than on the outer side.

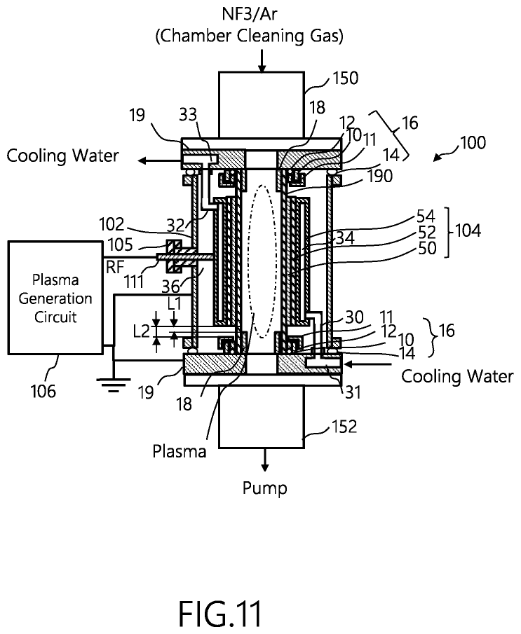

FIG. 11 is a cross-sectional view of an example of an exhaust pipe apparatus according to a second embodiment as viewed from the front side. A cross-sectional view of an example of the exhaust pipe apparatus according to the second embodiment as viewed from the upper side is not provided. FIG. 11 is the same as FIG. 2 except that ring-shaped protrusions 18 extending from the surfaces of the flanges 19 toward the radio-frequency electrode 104 are disposed on the inner side of the inner pipe 190.

Each protrusion 18 is made of a conductive material and functions as a part of the ground electrode. Each protrusion 18 is formed integrally with the flange 19 to which the protrusion is connected, for example.

Alternatively, each protrusion 18 may be formed separately from the flange 19 as long as it is electrically connected to the flange 19. In addition, when each O-ring retainer 11 is made of a conductive material, each O-ring retainer 11 functions as a part of the ground electrode by being brought into contact with the protrusion 10.

In the example of FIG. 11, since the tip of the protrusion 10 or the exposed surface of the O-ring retainer 11 on the side of the radio-frequency electrode 104 is closest to the radio-frequency electrode 104 on the outer side of the inner pipe 190, the protrusion 18 is formed such that the distance L1 between the tip of the protrusion 18 and the radio-frequency electrode 104 is smaller than the distance L2 between the tip of the protrusion 10 on the outer side of the inner pipe 190 or the exposed surface of the O-ring retainer 11 on the side of the radio-frequency electrode 104 and the radio-frequency electrode 104. When there is no protrusion 10, the protrusion 18 is disposed such that the distance L1 between the tip of the protrusion 18 and the radio-frequency electrode 104 is smaller than the distance between the flange surface on the outer side of the inner pipe 190 and the radio-frequency electrode 104. Accordingly, when a radio-frequency voltage is applied to the radio-frequency electrode 104, electric discharge occurs first between the protrusion 18 and the radio-frequency electrode 104. Therefore, for example, plasma by capacitive coupling can be generated inside the inner pipe 190 without applying a voltage that causes abnormal discharge (arcing) on the atmospheric pressure side. Decrease of the distance between the electrodes on the vacuum side can further enhance ignitability and stability of plasma in addition to suppression of arcing.

Note that it is desirable that the protrusion 18 be disposed such that the distance L1 between the tip of the protrusion 18 and the radio-frequency electrode 104 is even smaller than the distance between the grounded outer pipe 102 and the radio-frequency electrode 104.

The rest of the configurations is similar to that in FIG. 2.

As described above, according to the second embodiment, in addition to the same effects as those of the first embodiment, it is possible to further remove products deposited inside the exhaust pipe near the vacuum pump while avoiding abnormal discharge such as arcing.

### Third Embodiment

In each of the above-described embodiments, the configuration has been described in which the inner pipe 190 in close contact with the radio-frequency electrode 104 is directly cooled by flowing the cooling water into the cavity 34 in the hollow structure 54. A configuration in which the cooling mechanism of the third embodiment cools the space 36 between the inner pipe 190 and the outer pipe 102 will be further described.

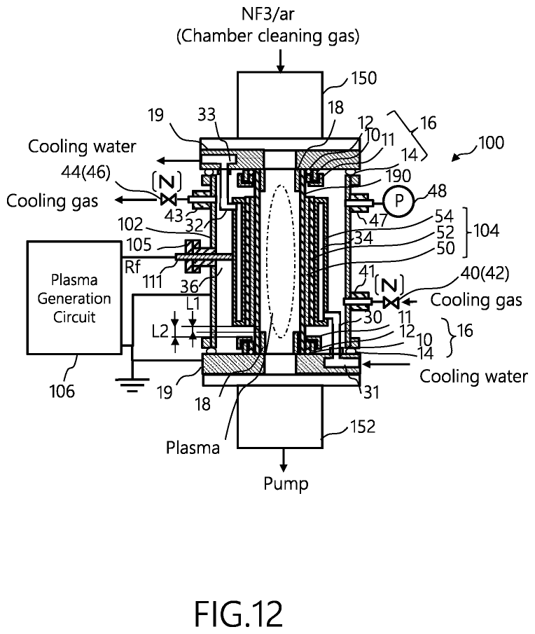

FIG. 12 is a cross-sectional view of an example of an exhaust pipe apparatus according to a third embodiment as viewed from the front side. A cross-sectional view of an example of the exhaust pipe apparatus according to the third embodiment as viewed from the upper side is not provided. FIG. 12 is the same as FIG. 11 except that a gas introduction port 41, a valve 40 (or a check valve 42), a gas discharge port 43, and a valve 44 (or a check valve 46) are further added. The cooling mechanism in the third embodiment introduces a cooling gas (another example of a refrigerant) into the space 36 between the inner pipe 190 and the outer pipe 102 from the gas introduction port 41 disposed on the lower side of the outer peripheral surface of the outer pipe 102 via the valve 40 (or the check valve 42). Then, the cooling gas is discharged to the outside from the gas discharge port 43 provided in an upper portion of the outer peripheral surface of the outer pipe 102 via the valve 44 (or the check valve 46). By allowing the cooling gas to flow into the space 36 between the inner pipe 190 and the outer pipe 102, the inner pipe 190, which is a dielectric pipe whose temperature rises due to plasma generation inside, and the space 36 between the inner pipe 190 and the outer pipe 102 are cooled. By cooling the inner pipe 190 with the cooling gas, the effect of suppressing a damage of the inner pipe 190 can be further enhanced. As the cooling gas, for example, air is used.

The cooling gas is introduced into the space 36 between the inner pipe 190 and the outer pipe 102 at a pressure higher than atmospheric pressure. Therefore, the pressure in the space 36 between the inner pipe 190 and the outer pipe 102 is controlled to be higher than the pressure in the space inside the inner pipe 190 and the atmospheric pressure. The pressure in the space 36 between the inner pipe 190 and the outer pipe 102 is measured by a pressure sensor 48 via a vent 47 disposed on the outer peripheral surface of the outer pipe 102, and fluctuations in the pressure in the space 36 are monitored. Here, in a case where the inner pipe 190, which is a dielectric pipe whose temperature rises due to plasma generation inside, is damaged, vacuum breakdown occurs when a large amount of cooling gas flows into the vacuum side. Therefore, the damage of the inner pipe 190 is detected by the pressure sensor 48.

Specifically, when pressure decrease is detected by the pressure sensor 48, control is performed to block the valves 40 and 44. As a result, the inflow of the cooling gas into the exhaust line can be minimized. In a case where the check valve 42 is used instead of the valve 40, the check valve 42 in which the cracking pressure is set such that the check valve 42 is blocked when the pressure difference between the primary pressure and the secondary pressure is higher than 0.1 MPa and lower than the supply pressure of the cooling gas is used. When the supply of the cooling gas is stopped at the supply source, the primary pressure (the primary side of the check valve) is equal to the atmospheric pressure, the secondary pressure (inside the outer pipe 102) is equal to or lower than the atmospheric pressure (the pressure decreases to be lower than the atmospheric pressure due to damage), and the differential pressure is equal to or lower than 0.1 MPa. Therefore, when 0.1 MPa<cracking pressure<supply pressure is satisfied, the cooling gas does not flow. Therefore, if the supply of the cooling gas is stopped at the supply source in response to the detection of the damage of the inner pipe 190, the atmospheric air can be prevented from flowing into the outer pipe 102 even when the primary side is opened to the atmospheric air. In a case where the check valve 46 is used instead of the valve 44, damage of the inner pipe 190 makes the primary pressure lower than the secondary pressure, so that the flow path can be blocked. Therefore, the atmospheric air can be prevented from flowing into the outer pipe 102.

The rest of configurations is similar to those in FIG. 11.

As described above, according to the third embodiment, in addition to the same effects as those of the first and second embodiments, the cooling effect of the inner pipe 190 can be further enhanced.

The embodiments have been described with reference to the specific examples. However, the present invention is not limited to these specific examples. For example, in the embodiments of the present invention, the exhaust pipe apparatus may be applied to a semiconductor manufacturing apparatus other than the film forming apparatus such as an etching apparatus.

In addition, all exhaust pipe apparatuses that include the elements of the present invention and can be achieved by appropriate modification of design by those skilled in the art fall in the scope of the present invention.

While certain embodiments have been described, these embodiments have been presented by way of example only, and are not intended to limit the scope of the inventions. Indeed, the novel methods and apparatuses described herein may be embodied in a variety of other forms; furthermore, various omissions, substitutions and changes in the form of the methods and apparatuses described herein may be made without departing from the spirit of the inventions. The accompanying claims and their equivalents are intended to cover such forms or modifications as would fall within the scope and spirit of the inventions.

What is claimed is:

1. An exhaust pipe apparatus functioning as a part of an exhaust pipe disposed between a process chamber and a vacuum pump that exhausts gas inside the process chamber, the apparatus comprising:
a dielectric pipe;
a radio-frequency electrode which includes a thin metal plate disposed on an outer periphery side of the dielectric pipe, a buffer member disposed on an outer periphery side of the thin metal plate, and a conductive hollow structure disposed on an outer periphery side of the buffer member and to which a radio-frequency voltage is applied; and
a plasma generation circuit that generates plasma inside the dielectric pipe.

2. The apparatus according to claim 1, further comprising a first cooling mechanism configured to introduce a first refrigerant into a space in the hollow structure and cool the dielectric pipe via the buffer member and the thin metal plate.

3. The apparatus according to claim 2, wherein cooling water is used as the first refrigerant.

4. The apparatus according to claim 1, wherein a thickness of the thin metal plate is thinner than a thickness of the hollow structure.

5. The apparatus according to claim 1, wherein the thin metal plate is disposed on the outer periphery side of the dielectric pipe in close contact with the dielectric pipe.

6. The apparatus according to claim 1, wherein
the radio-frequency voltage is applied to the hollow structure, and
the radio-frequency voltage is applied to the thin metal plate via the hollow structure, and
the hollow structure and the thin metal plate are electrically at substantially a same potential.

7. The apparatus according to claim 1, further comprising:
an outer pipe disposed outside the radio-frequency electrode; and
a second cooling mechanism configured to introduce a second refrigerant into a space between the dielectric pipe and the outer pipe and cool the dielectric pipe and the space between the dielectric pipe and the outer pipe.

8. The apparatus according to claim 7, wherein a cooling gas is used as the second refrigerant.

9. The apparatus according to claim 8, wherein the cooling gas is introduced at a pressure higher than atmospheric pressure.

10. The apparatus according to claim 7, further comprising a pressure sensor configured to measure a pressure in the space between the dielectric pipe and the outer pipe.

11. The apparatus according to claim 1, wherein
the hollow structure includes one half hollow structure and the other half hollow structure obtained by halving a circumference of a cylindrical shape, and
the hollow structure is formed as a combination of the one half hollow structure and the other half hollow structure.

12. The apparatus according to claim 11, wherein a cavity is formed in each of the one half hollow structure and the other half hollow structure.

13. The apparatus according to claim 12, further comprising a first cooling mechanism configured to introduce a first refrigerant into a space in the hollow structure and cool the dielectric pipe via the buffer member and the thin metal plate, wherein
the first cooling mechanism includes a pipe configured to connect the cavity of the one half hollow structure and the cavity of the other half hollow structure.

14. The apparatus according to claim 11, wherein the one half hollow structure and the other half hollow structure are electrically connected.

15. The apparatus according to claim 1, wherein
the buffer member includes one half buffer member and the other half buffer member obtained by halving a circumference of a cylindrical shape, and
the buffer member is formed as a combination of the one half buffer member and the other half buffer member.

16. The apparatus according to claim 15, wherein the buffer member is disposed so as to be in close contact with the thin metal plate with the thin metal plate sandwiched by the one half buffer member and the other half buffer member.

17. The apparatus according to claim 15, wherein
the hollow structure includes one half hollow structure and the other half hollow structure obtained by halving a circumference of a cylindrical shape,
the one half buffer member is disposed on an inner surface side of the one half hollow structure, and
the other half buffer member is disposed on an inner surface side of the other half hollow structure.

18. The apparatus according to claim 1, further comprising:
an outer pipe disposed outside the radio-frequency electrode; and
an introduction terminal that is introduced from outside to inside of the outer pipe and is connected to the radio-frequency electrode, wherein
the radio-frequency voltage is applied to the hollow structure via the introduction terminal.

19. The apparatus according to claim 1, further comprising a flange that is disposed on an end side of the dielectric pipe and configured to fix the dielectric pipe, wherein
the flange is grounded, and
the plasma is generated by a potential difference between the radio-frequency electrode and the flange.

20. The apparatus according to claim 19, further comprising a ring-shaped protrusion disposed on an inner side of the dielectric pipe so as to extend from the flange toward the radio-frequency electrode.
